(19) United States
(12) Patent Application Publication
(10) Pub. No.: US 2002/0174994 A1
(43) Pub. Date: Nov. 28, 2002

(54) EMI-protective device shell

(76) Inventor: Ko Lee Wu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/861,605

(22) Filed: May 22, 2001

(51) Int. Cl. H05K 9/00

(52) U.S. Cl. 174/35 R

(57) ABSTRACT

An EMI protective device shell having a covering layer of aluminum foil bonded to the smooth outside wall of the plastic shell body thereof and a layer of transparent protective coating spray-painted on the covering layer of aluminum foil.

### BACKGROUND OF THE INVENTION

The present invention relates to a device shell for an electronic apparatus, for example, cellular telephone, PDA, LCD module or the like, and, more particularly, to an EMI protective device shell, which comprises a plastic shell body and a covering layer of aluminum foil bonded to the outside wall of the shell body for EMI (electromagnetic interference) protection.

Various researches regarding the affect of the radiation of magnetic wave of a cellular telephone to human brain and human body have been reported. Related researches show the use causes temporary memory loss, headache, tiredness, deterioration of immunity, brain tumor, blood cancer, and etc. It is suggested not to closely attach the cellular telephone to the ear, or to attach a radiation shield to the cellular telephone when using it. The use of other electronic apparatus may also cause same problem. In order to eliminate the radiation of magnetic wave, electronic apparatus manufacturers may provide their electronic apparatus with a metal shield. However, the installation of the metal shield greatly increases the cost of the electronic apparatus. Furthermore, the metal shield cannot absolutely shields the electronic apparatus in all directions, i.e., the EMI protective effectiveness of the installation of a metal shield in an electronic apparatus is still not satisfactory.

### SUMMARY OF THE INVENTION

The present invention has been accomplished to provide an EMI protective device shell, which eliminates the aforesaid drawbacks. It is one object of the present invention to provide an EMI protective device shell, which effectively protects the internal circuit of the device against the interference of external noises and, shields the radiation of electromagnetic waves of the internal circuit of the device. It is another object of the present invention to provide an EMI protective device shell, which is inexpensive to manufacture. According to one aspect of the present invention, the EMI protective device shell comprises a plastic shell body for an electronic device, for example, a cellular telephone, PDA, LCD module, or the like, a covering layer of aluminum foil bonded to the smooth outside wall of the plastic shell body, and a layer of transparent protective coating spray-painted on the covering layer of aluminum foil. According to another aspect of the present invention, the covering layer of aluminum foil has a particular pattern or design obtained by means of a laser processing process.

### BRIEF DESCRIPTION OF THE DRAWINGS

FIG. 1 is an extended out view of a covering layer of aluminum foil for an EMI protective device shell according to the present invention.

FIG. 2 is an exploded view of the plastic top cover shell and plastic bottom cover shell of a cellular telephone shell before the bonding of the respective covering layer of aluminum foil according to the present invention.

FIG. 3 shows the plastic top cover shell and plastic bottom cover shell of the cellular telephone shell of FIG. 2 covered with a respective covering layer of aluminum foil according to the present invention.

FIG. 4 is an assembly view of FIG. 3.

FIG. 5 illustrates the shell of a camera covered with a covering layer of aluminum foil according to the present invention.

FIG. 6 illustrates the shell of a PDA covered with a covering layer of aluminum foil according to the present invention.

FIG. 7 illustrates the shell of a notebook computer covered with a covering layer of aluminum foil according to the present invention.

FIG. 8 illustrates the shell of a LCD module covered with a covering layer of aluminum foil according to the present invention.

FIG. 9A is a radiation chart obtained from a cellular telephone without the covering layer of aluminum foil.

FIG. 9B is a radiation chart obtained from a cellular telephone with the covering layer of aluminum foil according to the present invention.

### DETAILED DESCRIPTION OF THE PREFERRED EMBODIMENT

Referring to FIGS. from 1 through 4, a cellular telephone 30 is shown comprising a cellular telephone shell 20. The cellular telephone shell 20 is comprised of a plastic top cover shell 21 and a plastic bottom cover shell 22. The plastic top cover shell 21 and the plastic bottom cover shell 22 have the respective outside wall covered with a respective covering layer of aluminum foil 10. After adhesion to the outside wall of the plastic top cover shell 21 and the outside wall of the plastic bottom cover shell 22, the adhesive which secures the respective covering layer of aluminum foil 10 to the plastic top cover shell 21 and the plastic bottom cover shell 22 is dried by heat. After drying of the adhesive, the covering of aluminum foil 10 of each of the plastic top cover shell 21 and the plastic bottom cover shell 22 is respectively coated with a layer of transparent protective coating by spray-painting. Because the plastic top cover shell 21 and plastic bottom cover shell 22 of the cellular telephone shell 20 of the cellular telephone 30 are covered with a respective covering layer of aluminum foil 10, the cellular telephone shell 20 protects the internal circuit of the cellular telephone 30 against the interference of external noises and, shields the radiation of magnetic wave of the internal circuit of the cellular telephone 30 during its operation. Further, the covering layer of aluminum foil 10 for the plastic top cover shell 21 or plastic bottom cover shell 22 may be processed by laser to provide a pattern or design, so as to make the cellular telephone 30 more attractive and valuable. Because the top cover shell 21 and bottom cover shell 22 of the cellular telephone shell 20 are injection-molded from plastics and then covered with a respective covering layer of aluminum foil 10, the manufacturing cost of the cellular telephone shell 20 is low.

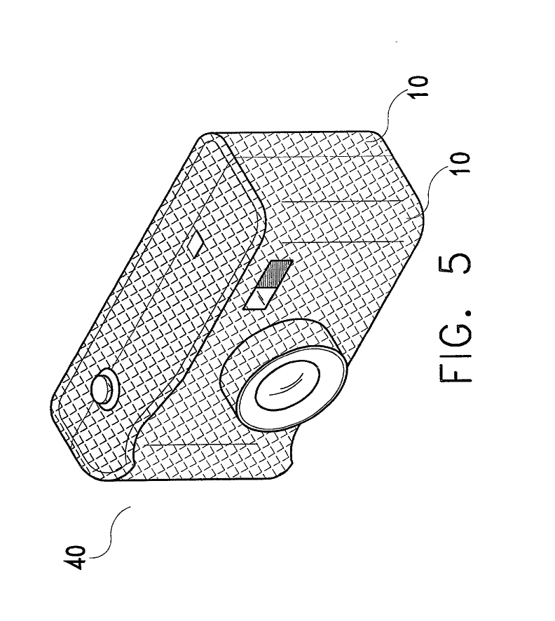

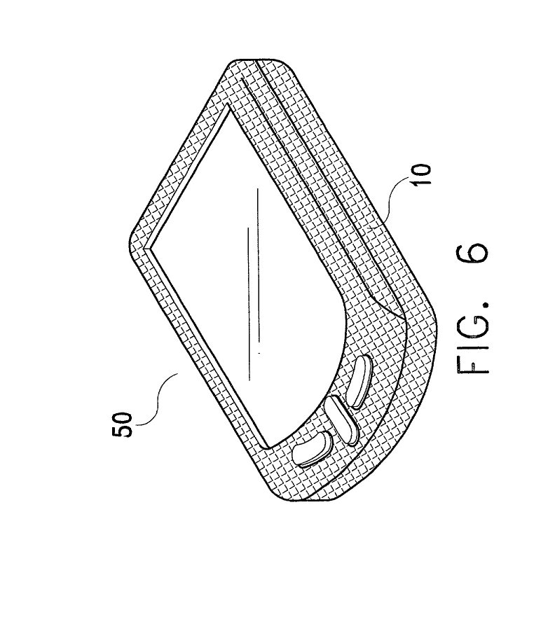

Referring to FIGS. 5 and 6, the shell of the camera 40 or PDA 50 has a covering layer of aluminum foil 10 adhered to the outside wall thereof and coated with a transparent protective layer of coating. The design of the covering layer of aluminum foil 10 makes the camera 40 or PDA 50 more attractive and valuable.

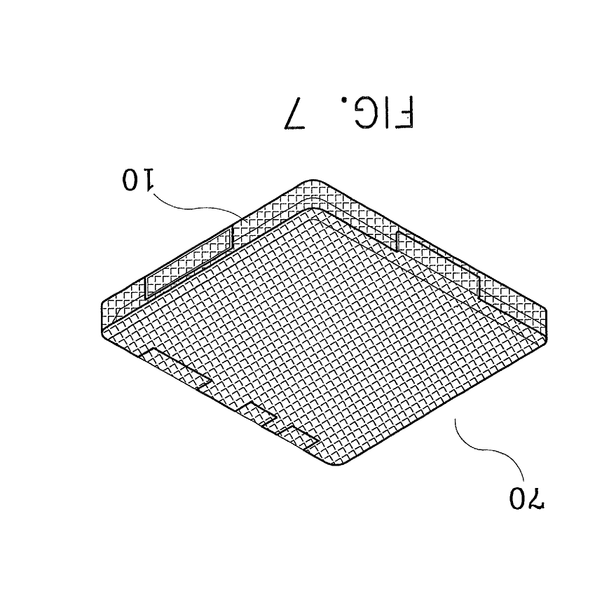

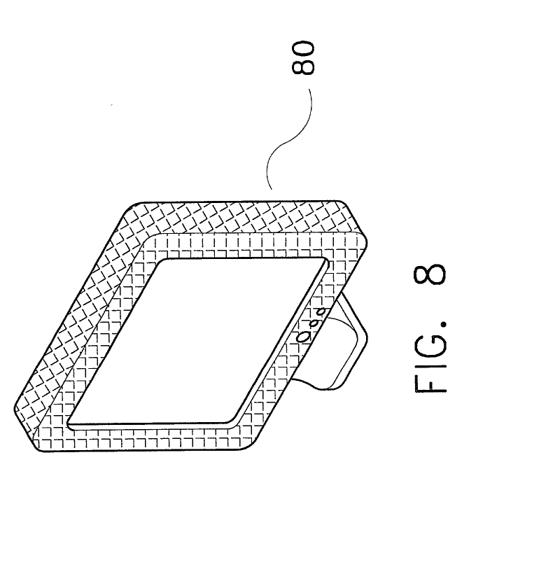

Referring to FIGS. 7 and 8, the shell of the notebook computer 70 or LCD module 80 has a covering layer of aluminum foil 10 adhered to the outside wall of the shell thereof and coated with a transparent protective layer of coating. The design of the covering layer of aluminum foil 10 makes the camera 40 or PDA 50 more attractive and valuable. According to this embodiment, the shell of the computer 70 or LCD module 80 is injection-molded from plastics for the advantages of low weight and low manufacturing cost. The covering layer of aluminum foil 10 protects the internal circuit of the computer 70 or LCD module 80 against interference of external noises and, shields the radiation of magnetic wave of the internal circuit of the computer 70 or LCD module 80.

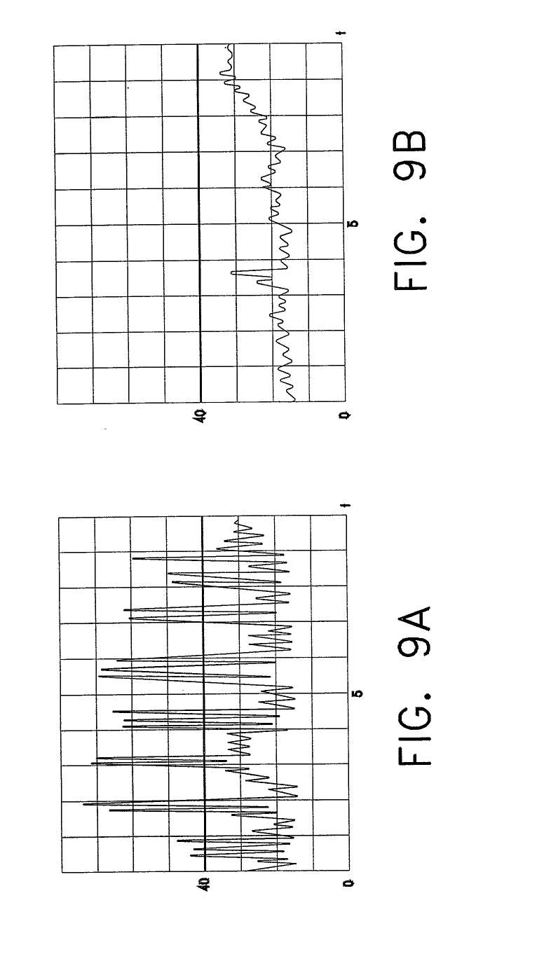

FIGS. 9A and 9B are radiation charts obtained from a cellular telephone without the covering layer of aluminum foil 10 and a cellular telephone with the covering layer of aluminum foil 10 respectively. As illustrated, the radiation of magnetic wave of the cellular telephone is attenuated and shielded by 60% after the installation of the covering layer of aluminum foil 10 of the present invention.

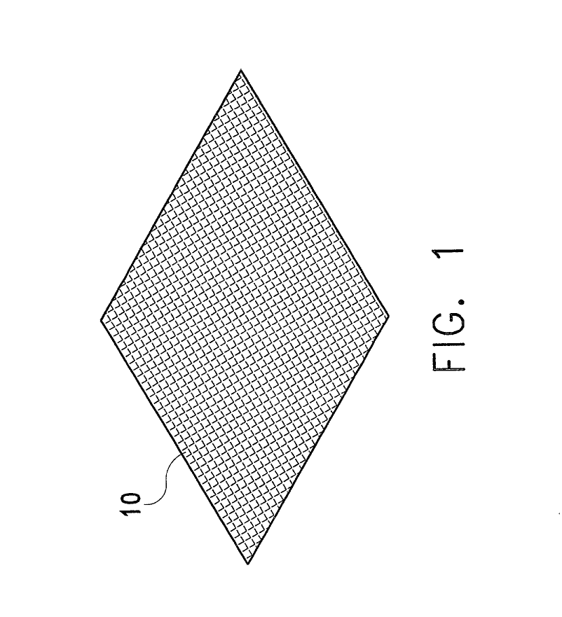

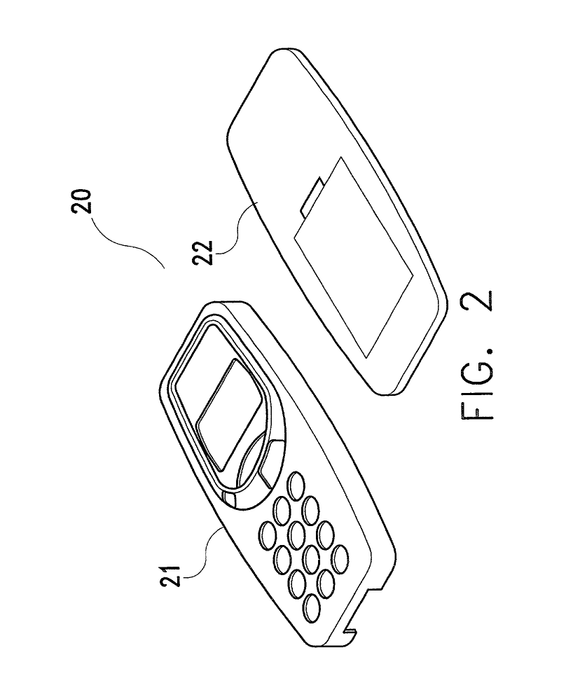

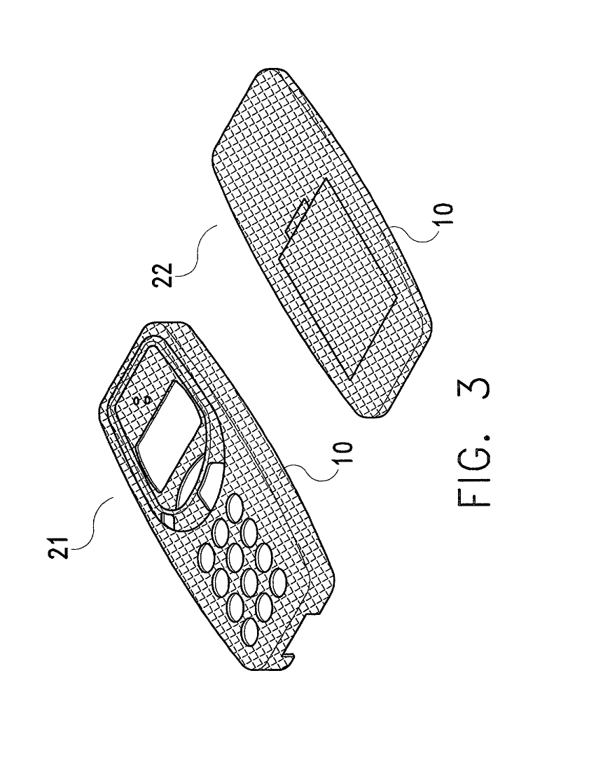

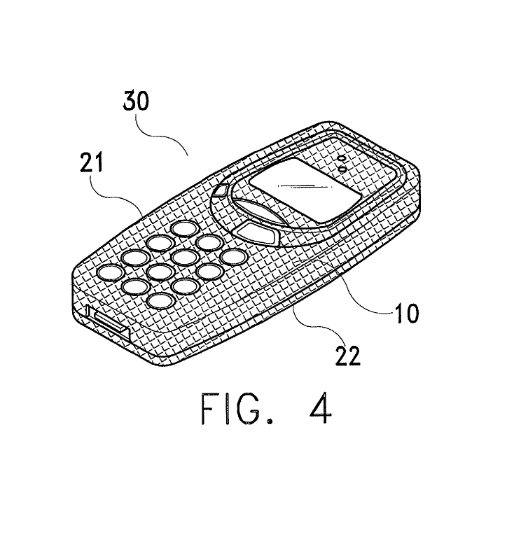

A prototype of EMI protective device shell has been constructed with the features of FIGS. 1˜8. The EMI protective device shell functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. An EMI protective device shell comprising a plastic shell body having a smooth outside wall, a covering layer of aluminum foil bonded to the smooth outside wall of said plastic shell body, and a layer of transparent protective coating spray-painted on said covering layer of aluminum foil.
